(19) United States
(12) Patent Application Publication
(10) Pub. No.: US 2006/0166450 A1
(43) Pub. Date: Jul. 27, 2006

(54) Method for manufacturing substrate

(75) Inventor: Takayuki Suzuki, Kanagawa (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, KANAGAWA (JP)

(21) Appl. No.: 11/333,315

(22) Filed: Jan. 18, 2006

(30) Foreign Application Priority Data
Jan. 25, 2005 (JP) 2005-017375

(51) Int. Cl. H01L 21/8222; H01L 21/331

(52) U.S. Cl. 438/311

(57) ABSTRACT

A substrate including an SOI region and a bulk region having an improved flatness is provided. In the process for manufacturing the patterned SOI substrate 100, a concave portion is previously produced by the bulk region 103 in silicon substrate 104. Therefore, the height of the step produced in the surface of the silicon substrate 104 can be reduced in the operation for forming the patterned SOI substrate 100. Accordingly, a certain level of the focus allowance in the exposure process, which has been difficult to be ensured in the conventional technology since steps were generated in the silicon substrate surface, can be ensured.

This application is based on Japanese patent application No. 2005-17375, the content of which is incorporated hereinto by reference.

### BACKGROUND

1. Technical Field

The present invention relates to a method for manufacturing a substrate including a silicon on insulator (SOT) region and a bulk region.

2. Related Art

An SOT device achieves an operation at higher operating frequency, as compared with a case of utilizing a non-SOI device. However, it is difficult to employ the SOT device for devices that require further operation stability, since the SOT device may exhibit unstable operation due to a floating body effect.

Therefore, existing designs of SOT cannot be utilized for devices that require further operation stability, and thus re-design of an SOT device is required. Consequently, a manner for exhibiting a predominance of SOT without a need for changing the design utilizes a patterned SOT substrate including both of an SOI region and a bulk region that is a non-SOI region.

Processes for manufacturing a patterned SOI substrate include a silicon implanted oxide (SIMOX) that employs a patterned mask. Such process includes a process for implanting oxygen (O₂) ion into a desired portion except the non-SOI region in the substrate having a pattern mask to form an SOI region (Japanese Patent Laid-Open No. H10-303385 (1998)).

However, a step may be created on the surface of the silicon substrate around a boundary between the SOI region and the bulk region that is the non-SOI region, during an operation for forming an embedded oxide film via an oxygen ion implantation in the conventional process for manufacturing the substrate. After the oxygen ion implantation, an internal thermal oxidation (ITOX) annealing is conducted within an oxygen atmosphere, in order to obtain the embedded oxide film layer having higher quality. While the surface of the silicon substrate is oxidized in this case, oxidizing rate for the SOI region is different from that for the bulk region that is the non-SOI region. Therefore, a step may be created on the surface of the silicon substrate around a boundary between the SOI region and the bulk region, which is the non-SOI region and exhibits a different level of oxidization from the SOI region, during the cleaning of the silicon substrate after the annealing (wet etching for oxide film).

A condition of the step created on the surface of the substrate is shown in FIG. 15, which is a plan view of a partial SOI substrate 10 viewed from an upper direction, and FIG. 16, which is a cross-sectional view of the substrate shown in FIG. 15 along line B-B′.

When the patterned SOI substrate 10 is formed via an SIMOX process that employs a pattern mask, a step is produced on a surface of a silicon substrate 4 at a boundary between an SOI region 2 and a bulk region 3 (FIG. 15 and FIG. 16). Although an exaggerated view is presented in FIG. 15, in which only the bulk region 3 is indicated as a hatched area while the SOI region 2 is indicated as an area without hatching on the surface of the silicon substrate 4, in order to present better viewing of the condition, both areas are the components of the silicon substrate. The surface of the SOI region 2 in the silicon substrate 4 is located at a level lower than the surface of the bulk region 3 that is the non-SOI region in the silicon substrate 4. The height of the step is approximately 0.2 μm.

As a miniaturization of LSI is progressed, manufacturing of devices becomes to be complicated, due to the existence of the step formed in the surface of the silicon substrate 4. In particular, under 90 nm-process rule, it is difficult to simultaneously form complementary metal oxide semiconductor (CMOS) devices having desired characteristics on the SOI region and on the non-SOI region, respectively, by employing the conventional SIMOX process. In other words, a distance from a light source to a resist formed on the SOI region is different from a distance from the light source to a resist formed on the bulk region, due to the step created in the surface of the substrate. This will provide different focusing allowances for the SOI region and for the bulk region that is the non-SOI region, in a process for patterning the photo resist in a later process. Therefore, an accuracy in the geometry of the patterned resist is reduced, leading to provide a difficulty in conducting a dimensional control.

In addition, when a device isolation oxide film is processed, the device isolation oxide film may be remained in the SOI region that has a concave portion in the surface of the substrate, thereby presenting a disproportional geometry of the device isolation, in which the SOI region and the non-SOI region is isolated. This may result in providing difficult dimensional control during the process for forming the gate. Further, a damage in the substrate may be caused or a residual material of the substrate may be generated. The reason thereof is that: a surface having higher flatness can be obtained by employing the CMP technology, and therefore, if the surface of the substrate has a step before conducting the CMP process, the film thickness in the SOI region of the CMP-processed device isolation oxide film is different from the film thickness in the bulk region thereof by the height of the step. Therefore, the height of the device isolation film is changed, resulting in variation of the film thickness of the resist (anti-reflective coating: ARC) in the process for forming the gate, depending on the points on the substrate. Accordingly, an excessive etching is caused in a region having a smaller thickness of the resist film, and an insufficient etching is caused in a region of having a larger thickness of the resist film during the process for etching the gate, and therefore, it is difficult to provide an improved processibility for the silicon substrate.

### SUMMARY OF THE INVENTION

According to one aspect of the present invention, there is provided a method for manufacturing a substrate having a silicon on insulator (SOI) region and a bulk region, including: providing a silicon substrate; etching a portion in a surface of said silicon substrate where a bulk region is to be formed; providing a mask, said mask having an opening on a portion of said silicon substrate where an SOI region is to be formed, and covering said portion of said silicon substrate where the bulk region is to be formed; forming the SOI region in said portion where the SOI region is to be formed and forming the bulk region in said portion where the bulk region is to be formed, by conducting an ion implantation over the entire surface of said silicon substrate under a condition where said mask is provided, and thereafter, conducting an annealing to form an oxide layer in an interior of the silicon substrate where the SOI region is to be formed; and etching said mask and the surface of said silicon substrate in said SOI region.

According to the present invention, the step around the boundary between the SOI region and the bulk region can be reduced by etching the surface of said silicon substrate in the portion where the bulk region is to be formed and etching the mask and the surface of the silicon substrate in the SOI region. Therefore, the substrate having the SOI region and the bulk region with an improved flatness can be manufactured.

According to the present invention, the substrate having the SOI region and the bulk region with an improved flatness can be manufactured.

### BRIEF DESCRIPTION OF THE DRAWINGS

The above and other objects, advantages and features of the present invention will be more apparent from the following description taken in conjunction with the accompanying drawings, in which:

FIG. 1 is a plan view, schematically illustrating a semiconductor device according to an embodiment;

FIG. 2 is a cross-sectional view, schematically illustrating the semiconductor device according to the embodiment;

FIG. 3 is a cross-sectional view of a semiconductor device, schematically illustrating a process for manufacturing the semiconductor device according to an embodiment;

FIG. 4 is a cross-sectional view of the semiconductor device, schematically illustrating the process for manufacturing the semiconductor device according to the embodiment;

FIG. 5 is a cross-sectional view of the semiconductor device, schematically illustrating the process for manufacturing the semiconductor device according to the embodiment;

FIG. 6 is a cross-sectional view of the semiconductor device, schematically illustrating the process for manufacturing the semiconductor device according to the embodiment;

FIG. 7 is a cross-sectional view of the semiconductor device, schematically illustrating the process for manufacturing the semiconductor device according to the embodiment;

FIG. 8 is a cross-sectional view of the semiconductor device, schematically illustrating the process for manufacturing the semiconductor device according to the embodiment;

FIG. 9 is a cross-sectional view of the semiconductor device, schematically illustrating the process for manufacturing the semiconductor device according to the embodiment;

FIG. 10 is a cross-sectional view of the semiconductor device, schematically illustrating the process for manufacturing the semiconductor device according to the embodiment;

FIG. 11 is a cross-sectional view of the semiconductor device, schematically illustrating the process for manufacturing the semiconductor device according to the embodiment;

FIG. 12 is a cross-sectional view of the semiconductor device, schematically illustrating the process for manufacturing the semiconductor device according to the embodiment;

FIG. 13 is a cross-sectional view of the semiconductor device, schematically illustrating the process for manufacturing the semiconductor device according to the embodiment;

FIG. 14 is a cross-sectional view of the semiconductor device, schematically illustrating the process for manufacturing the semiconductor device according to the embodiment;

FIG. 15 is a plan view, schematically illustrating a conventional semiconductor device; and

FIG. 16 is a cross-sectional view, schematically illustrating the conventional semiconductor device.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposed.

Preferable embodiments according to the present invention will be described as follows in further detail, in reference to the annexed figures. In all figures, an identical numeral is assigned to an element commonly appeared in the figures, and the detailed description thereof will not be presented.

Structure of a patterned SOI substrate 100 according to the present embodiment will be described as follows.

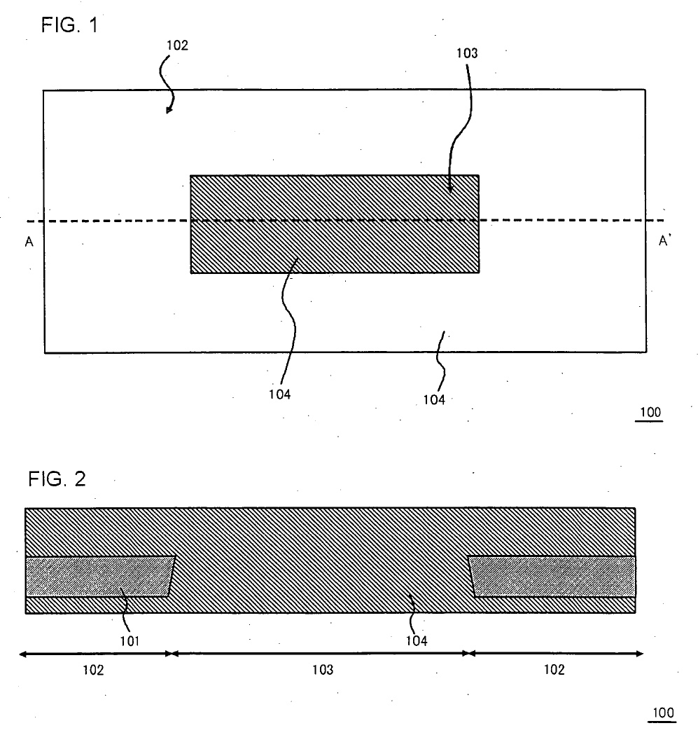

A plan view of the patterned SOI substrate 100 is shown in FIG. 1. A cross-sectional view along a plane A-A′ appeared in FIG. 1 is shown in FIG. 2.

As shown in FIG. 1, a bulk region 103 that is a non-SOI region is provided in a central portion of the patterned SOI substrate 100, and an SOI region 102 is provided in a circumference portion thereof. Although an exaggerated view is presented in FIG. 1, in which only the bulk region 103 is indicated as a hatched area while the SOI region 102 is indicated as an area without hatching on the surface of the silicon substrate 104, in order to present better viewing of the condition, both areas are components of the silicon substrate 104.

As shown in FIG. 2, the patterned SOI substrate 100 includes an oxide layer 101 provided within the silicon substrate 104 in the SOI region 102.

The patterned SOI substrate 100 is a substrate including the SOI region 102 and the bulk region 103. Therefore, the device formed on the substrate can be stably operated, while characteristic of having higher operating frequency that the SOI structure has can be maintained. Alternatively, the patterned SOI substrate 100 may also be a partial SOI substrate or a hybrid SOI substrate.

The SOI (Silicon on Insulator) region 102 is a region including so-called SOI structure, in which an oxide film 101 is sandwiched between the portions of the silicon substrate 104.

The bulk region 103 is a region having no SOI structure.

In the patterned SOI substrate 100, no step is created in the surface of the silicon substrate 104, and therefore the substrate has a substantially flat geometry. Here, “substantially flat” indicates tolerating an error within an range for providing an improved processibility for depositing a film on the patterned SOI substrate 100.

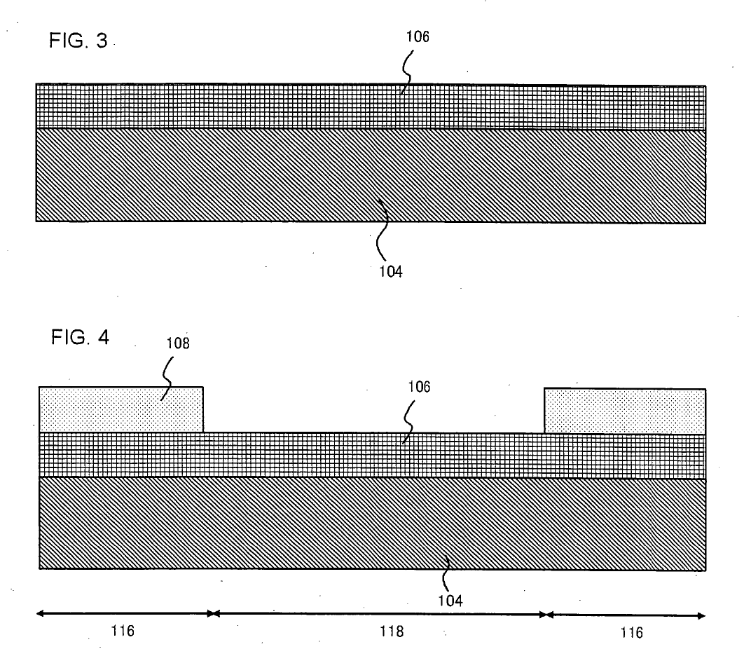

The process for manufacturing the patterned SOI substrate 100 having substantially flat surface of the silicon substrate 104 will be described in reference to FIG. 3 to FIG. 13 as follows.

The process for manufacturing the patterned SOI substrate 100 according to the present embodiment includes the following operations:

(i) first operation for providing the silicon substrate 104;

(ii) second operation for etching the surface of a portion 118 of the silicon substrate 104 where a bulk region is to be formed (FIGS. 3 to 7);

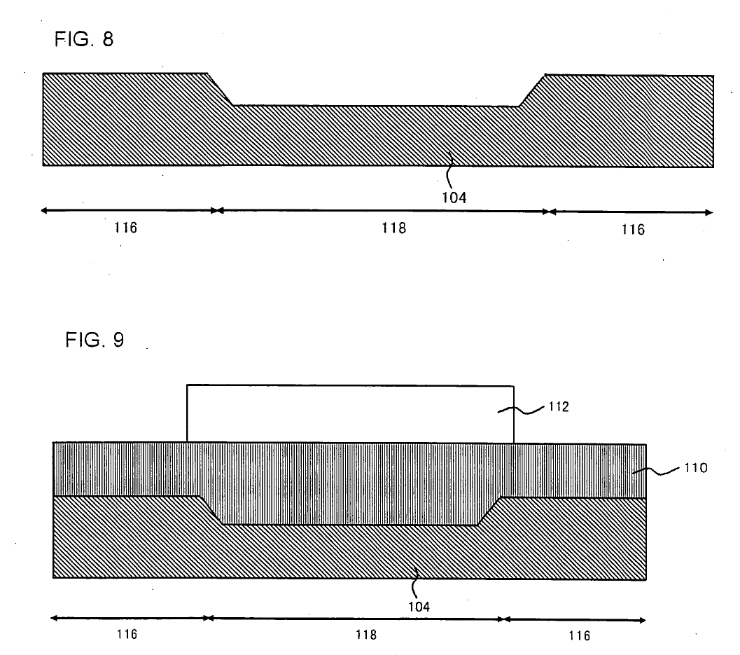

(iii) third operation for providing a mask 110, which has an opening on a portion 116 of the silicon substrate 104 where an SOI region is to be formed, and covers the portion 118 of the silicon substrate 104 where the bulk region is to be formed (FIGS. 8 to 11);

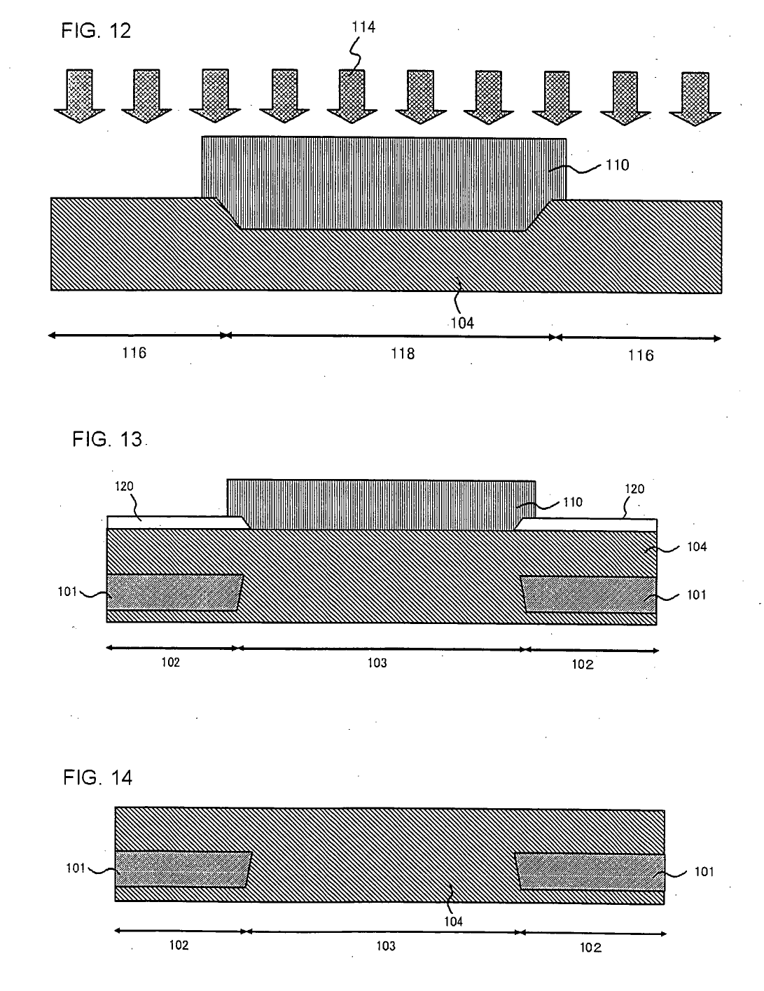

(iv) fourth operation for forming the SOI region 102 in the portion 116 where the SOI region is to be formed and forming the bulk region 103 in the portion 118 where the bulk region is to be formed, by conducting an ion implantation (oxygen ion 114) over the entire surface of the silicon substrate 104 under a condition where the mask 110 is provided, and thereafter, conducting an annealing to form an oxide layer 101 in an interior of the portion 116 of the silicon substrate 104 where the SOI region is to be formed (FIGS. 12 and 13); and

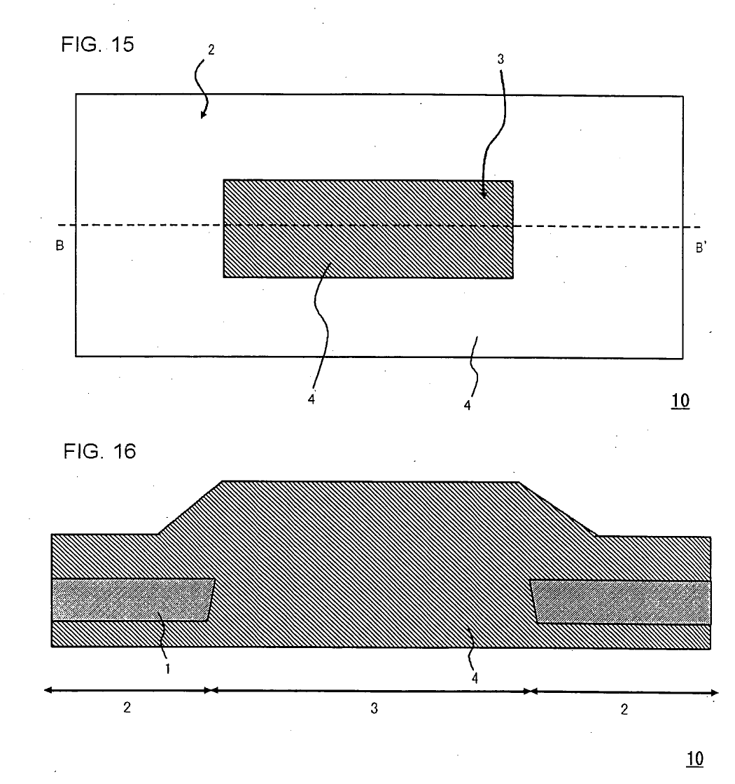

(v) fifth operation for etching the mask 110 and the surface of the silicon substrate 104 in the SOI region 102 (FIGS. 13 and 14).

Description will be made along each operation as follows.

First of all, the silicon substrate 104 is provided (first operation), and the mask 106 is formed so as to cover the entire upper surface of the silicon substrate 104 (FIG. 3). Next, a photo resist (not shown) is provided so as to cover the entire upper surface of the mask 106. Then, the photo resist 108 is patterned to be opened only on the portion 118 where the bulk region is to be formed and cover the portion 116 where the SOI region is to be formed 116 (FIG. 4). Here, the portion 118 where the bulk region is to be formed is a region to be converted to the bulk region 103, and the portion 116 where the SOI region is to be formed is a region to be converted to the SOI region 102.

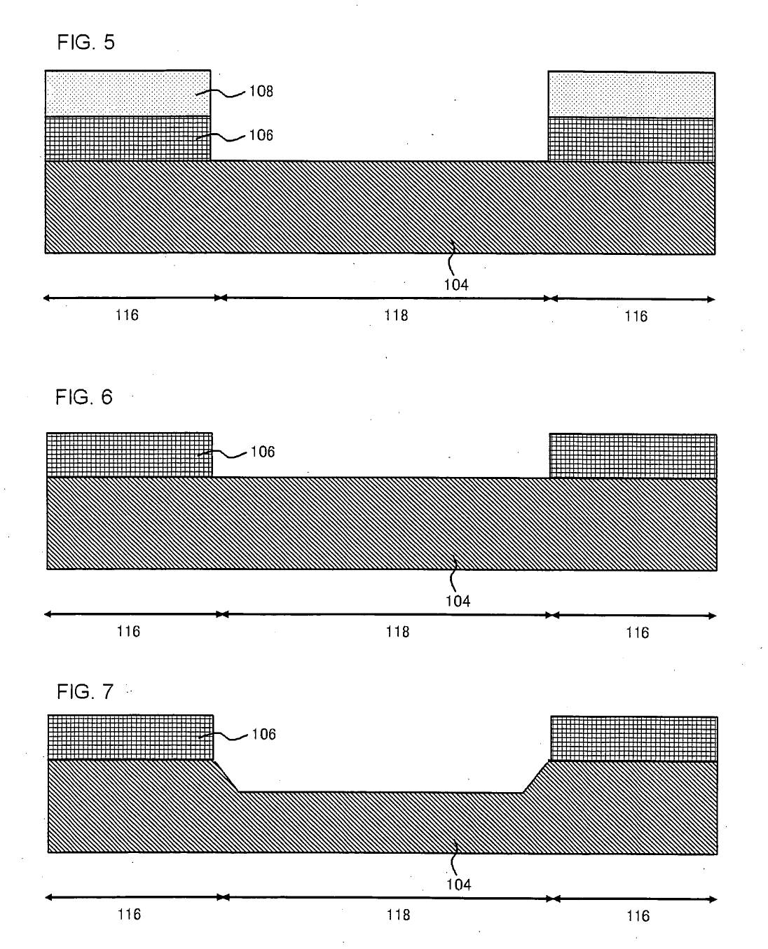

Subsequently, only the mask 106 in the portion 118 where the bulk region is to be formed is etched through the mask of the patterned photo resist 108 (FIG. 5). Then, the photo resist 108 is stripped (FIG. 6).

Next, the surface of the silicon substrate 104 in the portion 118 where the bulk region is to be formed is dry etched (second operation). Since the portion 116 where the SOI region is to be formed is masked with the mask 106 in this case, only the silicon substrate 104 in the portion 118 where the bulk region is to be formed 118 is etched (FIG. 7). Here, conditions such as etching temperature, etching time are suitably adjusted so that the geometry of the surface of the silicon substrate 104 is substantially flat when the oxide film 120 shown in FIG. 13 is removed after conducting an annealing process discussed later. More specifically, the etching conditions are suitably adjusted corresponding to annealing conditions such as annealing temperature or annealing time as will discussed later. As such, the removal depths in the selective removal of the surface of the silicon substrate 104 can be determined by appropriately adjusting the condition for the etching process. In the present embodiment, the conditions for the etching process are selected so that the thickness of the silicon substrate 104 is reduced by 0.2 μm. Then, the mask 106 is removed (FIG. 8)

Processes for converting the portion 116 where the SOI region is to be formed to the SOI region 102 and for converting the portion 118 where a bulk region is to be formed to the bulk region 103 by employing an SIMOX process will be described as follows. Further, the SOI region 102 is isolated from the bulk region 103 that are the non-SOI region by a process described as follows.

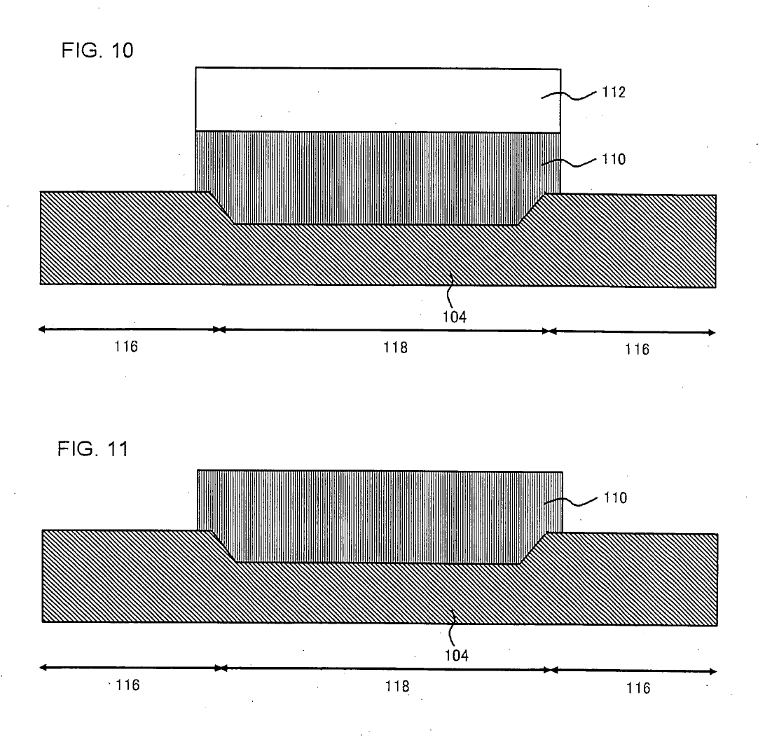

First of all, the mask 110, which is a hard mask for masking the portion 118 where the bulk region is to be formed 118, is formed on the silicon substrate 104, and a resist 112 for patterning the mask 110 is formed on the mask 110 (FIG. 9). In this case, the mask 110 is composed of a silicon oxide film. Next, a part of the mask 110 located on the portion 116 where the SOI region is to be formed is stripped through a mask of the resist 112 (FIG. 10). Subsequently, the resist 112 is stripped to provide a condition, in which only the surface of silicon substrate 104 in the portion 116 where the SOI region is to be formed is partially exposed (FIG. 11 (third operation)).

Subsequently, oxygen ion 114 is implanted over the entire surface of the silicon substrate 104 (FIG. 12). Since the portion 118 where the bulk region is to be formed is masked with the mask 110 in this case, the implantation of oxygen to the portion 118 where the bulk region is to be formed is prevented.

After implanting oxygen ion 114, the silicon substrate 104 is annealed by employing an ITOX technology within an oxygen atmosphere. An oxide layer 101 is formed in an interior of the silicon substrate 104 in the portion 116 where the SOI region is to be formed 116 by the annealing process to create an oxide film 120 that is a silicon oxide film in vicinity of the surface of the silicon substrate 104. Processing temperature and processing time, which are the conditions for the annealing process, are selected so as to provide a preferable formation of the oxide layer 101. The portion 116 where the SOI region is to be formed is converted to the SOI region 102, and the portion 118 where the bulk region is to be formed 118 is converted to the bulk region 103 (FIG. 13 (fourth operation)). After the annealing process, the mask 110 is stripped by a wet etching, and simultaneously the oxide film 120 on the surface of the silicon substrate 104 is also removed. Here, since the mask 110 is composed of the silicon oxide film, an etch rate for the mask is closer to that for the oxide film 120, and therefore the simultaneous removal of the mask 110 and the oxide film 120 is facilitated. While the oxide film 120 is formed on the surface of the silicon substrate 104 by conducting the annealing process employing the ITOX technology within the oxygen atmosphere after oxygen ion 114 is implanted, the patterned SOI substrate 100 including the silicon substrate 104 having the substantially flat surface geometry is formed when the oxide film 120 is removed, since the convex part is provided in the surface of the silicon substrate 104 in advance as show in FIG. 7 (FIG. 14 (fifth operation)). Here, “substantially flat” indicates tolerating an error within an range for providing an improved processibility for depositing a film on the patterned SOI substrate 100.

Advantageous effects obtainable by employing the configuration of the patterned SOI substrate 100 will be described as follows.

In the process for manufacturing the patterned SOI substrate 100, a concave portion is previously produced by conducting the etching process in the portion 118 where the bulk region is to be formed that will be converted to the bulk region 103 in the patterned SOI substrate 100, which could otherwise have a convex surface in the conventional technology. Therefore, the height of the step produced in the surface of the silicon substrate 104 can be reduced in the operation for forming the patterned SOI substrate 100. Accordingly, a certain level of the focus allowance in the exposure process, which has been difficult to be ensured in the conventional technology since steps were generated in the silicon substrate surface, can be ensured according to the present embodiment, thereby providing an improved dimensional accuracy for patterning the photo resist. As a result, CMOS devices having desired characteristics can be formed simultaneously on the SOI region 102 and on the bulk region 103, respectively, by employing the SIMOX process. Further, devices such as CMOS devices and the like can be produced on the silicon substrate 104, even if the LSI is further miniaturized.

Further, there has been the case in the conventional technology that a device isolation film is remained after the CMP process, since the surface of SOI region in the silicon substrate includes a concave portion during the CMP process. On the contrary, the formation of the concave portion of the silicon substrate 104 in the SOI region 102 can be inhibited by employing the patterned SOI substrate 100 according to the present embodiment. Therefore, remaining of the device isolation film in the SOI region 102 after the CMP process can be inhibited, so that the heights of respective portions of the device isolation film in the silicon substrate 104 can be equalized. Accordingly, uniform film thickness of the resist (anti-reflective coating: ARC) can be presented in the process for forming the gate, regardless of locations in the substrate. As a result, an excessive etching or an insufficient etching caused during the process for etching the gate can be inhibited, thereby providing an improved processibility for manufacturing the silicon substrate 104.

While the preferred embodiments of the present invention have been described above in reference to the annexed figures, it should be understood that the disclosures above are presented for the purpose of illustrating the present invention, and various configurations other than the above described configurations can also be adopted.

For example, while the configuration for achieving the reduction of the thickness of the silicon substrate 104 by the dry etching process has been described in the above-described embodiment, the reduction of the thickness of the silicon substrate 104 may be achieved by a wet etching process.

Further, while the configuration for forming the patterned SOI substrate 100 including the silicon substrate 104 having the flat surface has been described in the above-described embodiment, it is sufficient to achieve appropriately reducing the height of the step created at the boundary between the SOI region 102 and the bulk region 103 in the surface of the silicon substrate 104.

Further, while the configuration for forming the oxide layer 101 by conducting the ITOX annealing within the oxygen atmosphere has been described in the above-described embodiment, the oxide layer 101 may be formed by employing other type of annealing technology.

Further, while the configuration for stripping the mask 110 and simultaneously removing the oxide film 120 via the wet etching process has been described in the above-described embodiment, the mask 110 and the oxide film 120 may be removed via a dry etching process.

Further, while the configuration for having the mask 110 composed of the silicon oxide film has been described in the above-described embodiment, the mask 110 may be composed of other type of material.

It is apparent that the present invention is not limited to the above embodiment, that may be modified and changed without departing from the scope and spirit of the invention.

What is claimed is:

1. A method for manufacturing a substrate having a silicon on insulator (SOI) region and a bulk region, comprising:
providing a silicon substrate;
etching a portion in a surface of said silicon substrate where a bulk region is to be formed;
providing a mask, said mask having an opening on a portion of said silicon substrate where an SOI region is to be formed, and covering said portion of said silicon substrate where the bulk region is to be formed;
forming the SOI region in said portion where the SOI region is to be formed and forming the bulk region in said portion where the bulk region is to be formed, by conducting an ion implantation over the entire surface of said silicon substrate under a condition where said mask is provided, and thereafter, conducting an annealing to form an oxide layer in an interior of the silicon substrate where the SOI region is to be formed; and
etching said mask and the surface of said silicon substrate in said SOI region.

2. The method according to claim 1, wherein said etching said mask and the surface of said silicon substrate in said SOI region comprises etching to form a substantially flat entire surface of said silicon substrate.

3. The method according to claim 1, wherein said forming the SOI region further comprises forming a silicon oxide film on the surface of said silicon substrate in said SOI region by conducting said annealing within an oxygen atmosphere, and wherein said etching the mask and the surface of said silicon substrate in said SOI region comprises etching said mask and said silicon oxide film in said SOI region.

4. The method according to claim 1, wherein said mask is a silicon oxide film.
